(19) United States
(12) Patent Application Publication
(10) Pub. No.: US 2022/0415978 A1
(43) Pub. Date: Dec. 29, 2022

(54) DISPLAY PANEL AND MANUFACTURING METHOD THEREOF

(71) Applicant: WUHAN CHINA STAR OPTOELECTRONICS SEMICONDUCTOR DISPLAY TECHNOLOGY CO., LTD., Wuhan (CN)

(72) Inventor: Qian Huang, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 17/263,886

(22) PCT Filed: Sep. 3, 2020
(86) PCT No.: PCT/CN2020/113277

§ 371 Date: Jan. 27, 2021

(30) Foreign Application Priority Data
Jul. 6, 2020 (CN) 202010638526.8

(51) Int. Cl. H01L 27/32; H01L 51/56; H01L 51/00

(52) U.S. Cl. CPC H01L 27/3246; H01L 51/56; H01L 51/0019; H01L 2227/323

(57) ABSTRACT

The present invention provides a display panel and a manufacturing method thereof, wherein the display panel includes: a thin-film transistor array substrate; an anode disposed on the thin-film transistor array substrate; a pixel definition layer disposed on the anode and the thin-film transistor array substrate, wherein the pixel definition layer includes a first area and a second area, the first area is provided with an opening, a bottom of the opening is connected to the anode, and the second area is provided with a plurality of grooves; a light-emitting layer disposed in the opening; a cathode covering the light-emitting layer and the pixel definition layer; and an encapsulation layer covering the cathode.

### BACKGROUND OF INVENTION

### Field of Invention

The present invention relates to the field of display technology, in particular to a display panel and a manufacturing method thereof.

### Description of Prior Art

An organic light-emitting diode (OLED), as a current-type light-emitting device, has attracted wide attention because of its self-luminous characteristics, rich color, fast response speeds, wide viewing angles, light weight, and flexible display.

In an organic light-emitting diode display panel, low-temperature evaporation technology is often used for formation of a light-emitting functional layer. However, adhesion between organic layers of a light-emitting device produced by this technology is poor, which causes a structure of the light-emitting functional layer of the display panel to easily strip during a bending process, thereby impacting the stability of the display panel.

Therefore, there is a need to propose a new technical solution to solve the above technical problems.

Embodiments of the present invention provide a display panel and a manufacturing method thereof to improve the stability of the display panel.

### SUMMARY OF INVENTION

An embodiment of the present invention provides a display panel, including:

a thin-film transistor array substrate;

an anode disposed on the thin-film transistor array substrate;

a pixel definition layer disposed on the anode and the thin-film transistor array substrate, wherein the pixel definition layer includes a first area and a second area, the first area is provided with an opening, a bottom of the opening is connected to the anode, and the second area is provided with a plurality of grooves;

a light-emitting layer disposed in the opening;

a cathode covering the light-emitting layer and the pixel definition layer;

and

an encapsulation layer covering the cathode.

In the display panel provided by an embodiment of the present invention, the grooves are formed by pad printing.

In the display panel provided by an embodiment of the present invention, the grooves include a first groove and at least one second groove, and an opening of the at least one second groove is located on a sidewall and/or a bottom of the first groove.

In the display panel provided by an embodiment of the present invention, an opening of the first groove is larger than the opening of the second groove.

In the display panel provided by an embodiment of the present invention, the second groove at the bottom of the first groove is vertically embedded on the pixel definition layer, and an embedding angle of the second groove on each of opposite sides is greater than or equal to 0 degree and less than 90 degrees with respect to a horizontal plane of the pixel definition layer.

In the display panel provided by an embodiment of the present invention, a depth of the grooves is smaller than a thickness of the pixel definition layer.

In the display panel provided by an embodiment of the present invention, the depth of the grooves ranges between 0.2 μm and 1.2 μm.

In the display panel provided by an embodiment of the present invention, the display panel further includes a filling layer filling at least part of the grooves.

In the display panel provided by an embodiment of the present invention, a material of the filling layer includes an inorganic material.

In the display panel provided by an embodiment of the present invention, the inorganic material includes at least one of silicon oxide, silicon nitride, silicon carbide, silicon oxynitride, or inorganic oxide.

Another embodiment of the present invention also provides a method of manufacturing a display panel, including:

step A: forming a thin-film transistor array substrate;

step B: forming an anode on the thin-film transistor array substrate;

step C: forming a pixel definition layer, wherein the pixel definition layer includes a first area and a second area, the first area is provided with an opening, and the second area is provided with a plurality of grooves;

step D: forming a light-emitting layer in the opening;

step E: forming a cathode to cover the light-emitting layer and the pixel definition layer; and

step F: forming an encapsulation layer to cover the cathode.

In the method of manufacturing the display panel provided by an embodiment of the present invention, the step C includes:

step c1: forming a pixel definition material layer;

step c2: patterning the first area to form the opening;

step c3: pad printing the second area to form the grooves, wherein the grooves include a first groove and at least one second groove, and an opening of the at least one second groove is located on a sidewall and/or a bottom of the first groove.

In the method of manufacturing the display panel provided by an embodiment of the present invention, an opening of the first groove is larger than the opening of the second groove.

In the method of manufacturing the display panel provided by an embodiment of the present invention, the second groove at the bottom of the first groove is vertically embedded on the pixel definition layer, and an embedding angle of the second groove on each of opposite sides is greater than or equal to 0 degree and less than 90 degrees with respect to a horizontal plane of the pixel definition layer.

In the method of manufacturing the display panel provided by an embodiment of the present invention, a depth of the grooves is smaller than a thickness of the pixel definition layer.

In the method of manufacturing the display panel provided by an embodiment of the present invention, a depth of the grooves ranges between 0.2 μm and 1.2 μm.

In the method of manufacturing the display panel provided by an embodiment of the present invention, after the step C, the method of manufacturing the display panel further includes a step G:

forming a filling layer to fill at least part of the grooves.

In the method of manufacturing the display panel provided by an embodiment of the present invention, a material of the filling layer includes an inorganic material.

In the method of manufacturing the display panel provided by an embodiment of the present invention, the inorganic material includes at least one of silicon oxide, silicon nitride, silicon carbide, silicon oxynitride, or inorganic oxide.

In the method of manufacturing the display panel provided by an embodiment of the present invention, a material of the filling layer includes an inorganic material.

Compared with the prior art, in the display panel and the manufacturing method thereof provided by embodiments of the present invention, the pixel definition layer is provided with the grooves, and a cathode material is filled in the grooves to increase a contact area between the cathode and the pixel definition layer and increase adhesion between the cathode and the pixel definition layer, so that the light-emitting layer is not easy to strip, thereby improving the stability of the display panel.

In addition, by providing a filling layer in the grooves, and making the material of the filling layer and the cathode material have the same polarity, the adhesion between the cathode and the pixel definition layer is further increased.

### BRIEF DESCRIPTION OF DRAWINGS

In order to more clearly illustrate the embodiments or the technical solutions of the existing art, the drawings illustrating the embodiments or the existing art will be briefly described below. Obviously, the drawings in the following description merely illustrate some embodiments of the present invention. Other drawings may also be obtained by those skilled in the art according to these drawings without paying creative work.

FIG. 1 is a schematic structural diagram of a display panel provided by an embodiment of the present invention.

FIG. 2 is another schematic structural diagram of a display panel provided by an embodiment of the present invention.

FIG. 3 is further another schematic structural diagram of a display panel provided by an embodiment of the present invention.

FIG. 4 is a schematic structural diagram of grooves in a display panel provided by an embodiment of the present invention.

FIG. 5 is a schematic diagram of arrangement of sub-pixels inside a display panel provided by an embodiment of the present invention.

FIG. 6 is a flowchart of a method of manufacturing a display panel provided by an embodiment of the present invention.

FIG. 7 is a flowchart of step S3 in the method of manufacturing the display panel provided by an embodiment of the present invention.

### DETAILED DESCRIPTION OF PREFERRED EMBODIMENTS

In order to make the objectives, technical solutions, and advantages of the present invention clearer, the present invention will be described in further detail below with reference to the accompanying drawings. Referring to the drawings, wherein the same reference symbols represent the same elements. The following description is based on the specific embodiments of the present invention, which should not be construed as limiting other specific embodiments of the present invention that are not detailed herein. The term “embodiment” used in this specification means an example, instance, or illustration. In addition, the article “a” used in this specification and appended claims can generally be construed as “one or more” unless otherwise specified or can be clearly determined to be the singular form from the context.

When a component is described as “on” another component, the components are formed in direct contact, and may also include embodiments in which additional features may be formed interposing the first and second features, such that the first and second features may not be in direct contact. When a component is described as “installed to” or “connected to” another component, it can be understood that a component is “directly installed” or “directly connected” to another component, or a component is “installed to” or “connected with” another component through an intermediate component.

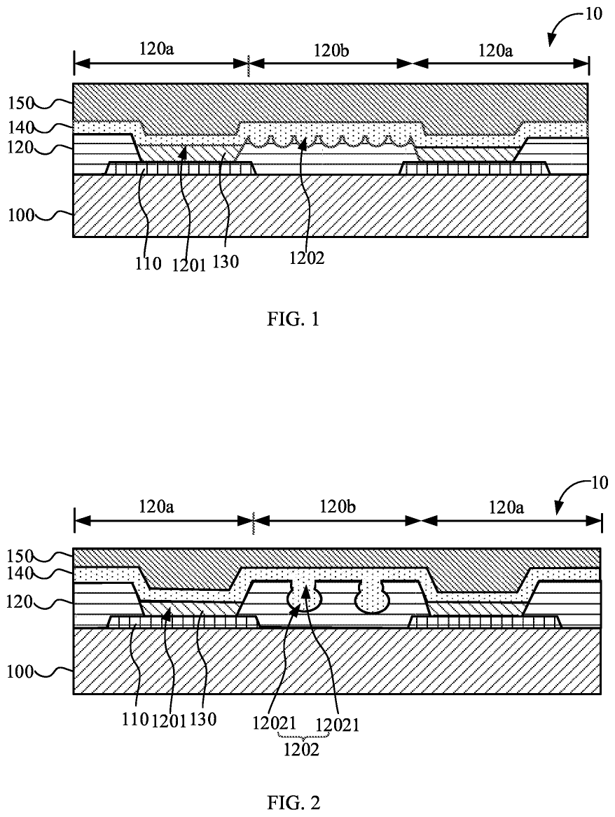

Referring to FIG. 1, an embodiment of the present invention provides a display panel. The display panel 10 includes a thin-film transistor array substrate 100, an anode 110, a pixel definition layer 120, a light-emitting layer 130, a cathode 140, and an encapsulation layer 150, wherein the thin-film transistor array substrate 100 includes: a substrate, a base layer, an active layer, a first gate insulating layer, a first gate, a second gate insulating layer, a second gate, an interlayer insulating layer, a source/drain, and a planarization layer (not shown).

The substrate layer includes a double-layered polyimide layer and a buffer layer arranged between the polyimide layer. It should be noted that the structure of the thin-film transistor substrate 100 in an embodiment of the present invention belongs to common general knowledge in the art, and the thin-film transistor in an embodiment of the present invention may also include other structures, which will not be repeated herein for brevity.

A first surface of the anode 110 is attached to a first surface of the thin-film transistor array substrate 100, and the anode 110 is connected to the source or drain on the thin-film transistor array substrate 100 through a via hole. The material of the anode 110 includes indium tin oxide (ITO).

The pixel definition layer 120 is disposed on the anode 110 and the thin-film transistor array substrate 100. The pixel definition layer 120 includes a first area 120a and a second area 120b, and the first area 120a is located on opposite sides of the second area 120b. The first area 120a is provided with an opening 1201, a bottom of the opening 1201 is connected to the anode 110, and the second area 120a is provided with a plurality of grooves 1202. Generally, the pixel definition layer 120 is an organic material layer. For example, the pixel definition layer 120 is made of at least one of organic materials including polyimide, polyamide, styrene, acrylic resin, silicone, polymethylmethacrylate (PMMA), and phenol resin.

The light-emitting layer 130 is disposed in the opening 1201 of the first area 120a. A material of the light-emitting layer 130 includes a fluorescent light-emitting material, a quantum dot light-emitting material, and the like.

The cathode 140 covers the light-emitting layer 130 and the pixel definition layer 120, and a material of the cathode 140 fills the grooves 1202; wherein the cathode material includes a metal with a low power function such as silver, lithium, magnesium, calcium, strontium, aluminum, and indium, or a metal compound, or an alloy.

The encapsulation layer 150 covers the cathode 140. The encapsulation layer 150 is configured to prevent the display panel from intrusion of water and oxygen.

Specifically, the grooves 1202 in an embodiment of the present invention are formed by surface embossing technology. Optionally, the grooves 1202 in an embodiment of the present invention may also be formed by pad printing technology, where the pad printing technology includes PI pad printing technology.

Optionally, referring to FIG. 2, FIG. 2 is another schematic structural diagram of the display panel 100 in an embodiment of the present invention. The grooves 1202 include a first groove 12021 and at least one second groove 12022, wherein an opening of the at least one second groove 12022 is located on a sidewall and/or a bottom of the first groove 12021. Specifically, in the display panel provided by the present invention, the grooves 1202 is formed by a surface pad printing process. For example, a semicircular print head is provided to emboss on the second area 120b, then the first groove 12021 is formed by rolling the print head, and after that, a second embossing is performed on the first groove 12021 to form the second groove 12022. It is also possible to provide a print head with a specific shape as a main body of the print head, a plurality of coupling parts are arranged on a side and a bottom of the main body, and the first groove 12021 and the second groove 12022 are directly formed by embossing. It should be noted that, in an embodiment of the present invention, the shape of the print head can be adjusted according to actual requirements, which is not particularly limited herein.

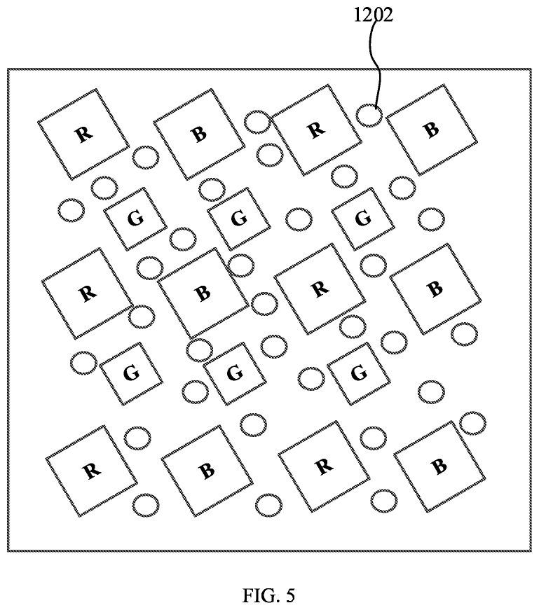

Optionally, referring to FIG. 4, FIG. 4 is another structural diagram of the grooves 1202 in an embodiment of the present invention. A number of the second groove 12022 is more than one. When the number of the second groove 12022 is greater than 1, the openings of the second grooves 12022 is located at a sidewall and a bottom of the first groove 12021, and an opening of the first groove 12022 is larger than the opening of the second groove 12022. Specifically, when the number of the second grooves 12022 is greater than 1, the second grooves 12022 are embedded in the pixel definition layer 120, and an embedding angle of each of the second grooves 12022 ranges from 90 degrees to 180 degrees. Specifically, the second groove 12021 at the bottom is vertically embedded on the pixel definition layer 120, and an embedding angle of each of the second grooves 12022 on each of opposite sides is greater than or equal to 0 degree and less than 90 degrees with respect to a horizontal plane of the pixel definition layer. This arrangement can further increase the contact area between the cathode and the pixel definition layer and prevent the light-emitting layer from striping.

It should be noted that in an embodiment of the present invention, the number and shapes of the grooves 1202 in the drawings are only examples, and not limitations of the present invention.

Further, a depth of the grooves 1202 is smaller than a thickness of the pixel definition layer. Optionally, the depth of the grooves 1202 ranges between 0.2 μm and 1.2 μm. For example, the depth of the grooves 1202 is any one of 0.2 micrometer, 0.2 micrometer, 0.3 micrometer, 0.4 micrometer, 0.5 micrometer, 0.6 micrometer, 0.7 micrometer, 0.8 micrometer, 0.9 micrometer, 1.0 micrometer, 1.1 micrometer, 1.2 micrometer.

In an embodiment of the present invention, the grooves are provided in the second area 120b of the pixel definition layer 120 to increase a contact area between the cathode 140 and the pixel definition layer 120 and increase adhesion between the cathode 140 and the pixel definition layer 120, so that the light-emitting layer is not easy to strip, thereby improving the stability of the display panel.

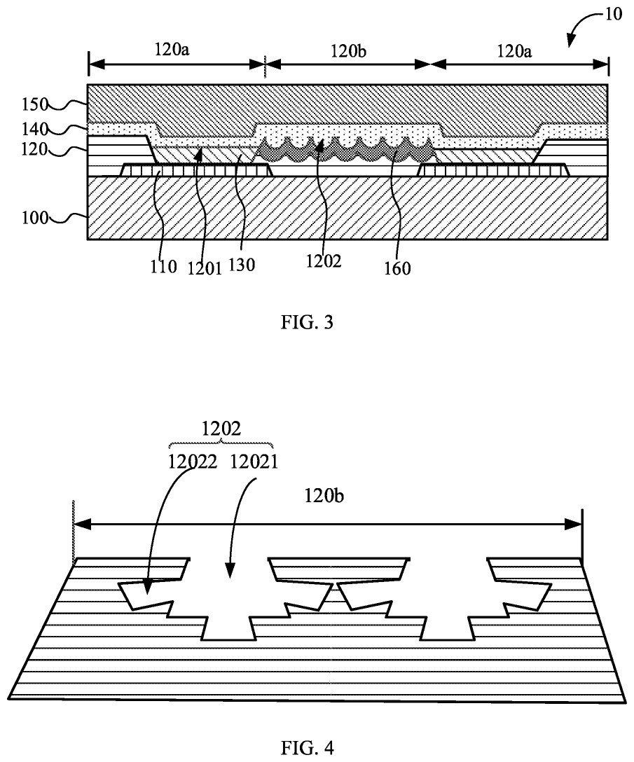

Optionally, referring to FIG. 3. FIG. 3 is another structural diagram of the display panel 10 in an embodiment of the present invention. The display panel 10 further includes a filling layer 160 filling at least part of the grooves 1202. The material of the filling layer 160 includes an inorganic material. For example, in some embodiments, the inorganic material includes at least one of silicon oxide, silicon nitride, silicon carbide, silicon oxynitride, or inorganic oxide. It is easy to understand that a bonding force between an inorganic material and a metal or a metal compound is better. Compared with the existing designs where adhesion between the cathode 140 and the pixel definition layer 120 relies on the Van der Waals force, the present invention improves the adhesiveness of the cathode 140, thereby effectively avoiding separation between the cathode 140 and the light-emitting layer 130 when the display panel is impacted or shocked, and an anti-bending strength and a strength of withstanding impact of the display panel are improved.

Referring to FIG. 5, in the display panel, the red sub-pixel R, the blue sub-pixel B, and the green sub-pixel G are arranged in a manner of RGBBR, that is, the red sub-pixel R and the blue sub-pixel B share a green sub-pixel G, to achieve the effect of high resolution, and such arrangement is called diamond arrangement. In the display panel provided by an embodiment of the present invention, due to a limitation of a size of a bottom circuit, the sub-pixels are not closely arranged, but there is a certain gap between each ones of the sub-pixels, that is, the gaps between the red sub-pixel R, the blue sub-pixel B, and the green sub-pixel G shown in FIG. 5. In an embodiment of the present invention, a plurality of grooves 1202 are provided at the gaps to increase the contact area between the cathode and the pixel definition layer, thereby increasing the adhesion between the cathode and the pixel definition layer, and preventing the light-emitting layer from striping.

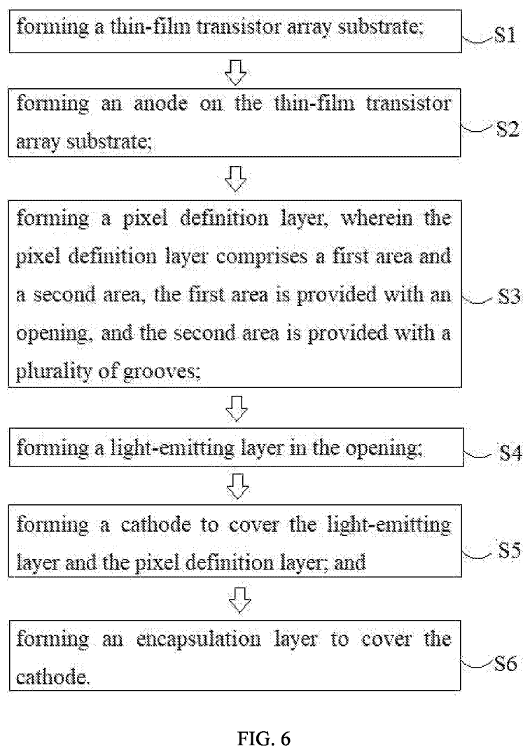

Referring to FIG. 1 and FIG. 6, another embodiment of the present invention also provides a method of manufacturing a display panel, including the following steps:

Step S1: forming a thin-film transistor array substrate 100;

Step S2: forming an anode 110, wherein a first surface of the anode 110 is attached to a first surface of the thin-film transistor array substrate 100;

Step S3: forming a pixel definition layer 120, wherein the pixel definition layer 120 includes a first area 120a and a second area 120b, the first area 120a includes an opening 1201, and the second area includes a plurality of grooves 1202;

Step S4: forming a light-emitting layer 130 in the opening 1201 of the first area 120a;

Step S5: forming a cathode 140 to cover the light-emitting layer 130 and the pixel definition layer 120; and

Step S6: forming an encapsulation layer 150 to cover the cathode 140.

Specifically, in the step S1, the thin-film transistor array substrate 100 includes: a substrate, a substrate layer, an active layer, a first gate insulating layer, a first gate, a second gate insulating layer, a second gate, and an interlayer Insulation layer, a source/drain, and a planarization layer.

The substrate layer includes a double-layered polyimide layer and a buffer layer arranged between the polyimide layer. It should be noted that the method of manufacturing thin-film transistor 100 in an embodiment of the present invention belongs to common general knowledge in the art, and the thin-film transistor in an embodiment of the present invention may also include other structures, which will not be repeated herein for brevity.

In the step S2, firstly, an anode material layer is formed on the thin-film transistor array substrate, a photoresist layer is formed on the anode material layer, and the photoresist layer and the anode material layer are patterned to form the anode 110, wherein the anode material of 110 includes indium tin oxide (ITO). The first surface of the anode 110 is attached to the first surface of the thin-film transistor array substrate 100, and the anode 110 is connected to the source or drain on the thin-film transistor array substrate 100 through a via hole.

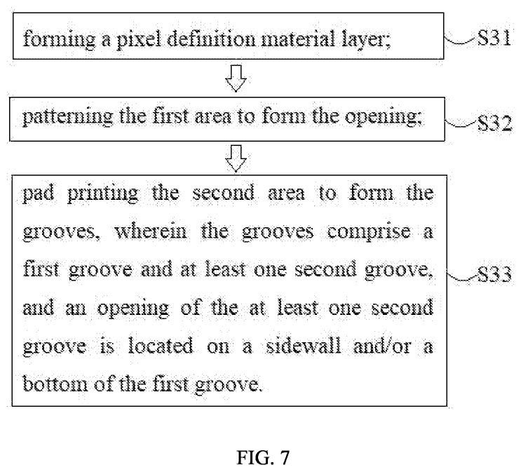

Referring to FIG. 2 and FIG. 7, optionally, the step S3 includes:

Step 31: forming a pixel definition material layer;

Step 32: patterning the first area 120a to form the opening 1201;

Step 33: pad printing the second area 120b to form the grooves 1202, wherein the grooves 1202 include a first groove 12021 and at least one second groove 12022, and an opening of the second groove 12022 is located on a sidewall and/or a bottom of the first groove 12021.

Specifically, a pixel defining material layer is formed on the anode 110 and the thin-film transistor array substrate 100, wherein the material of the pixel defining material layer includes at least one of organic materials including polyimide, polyamide, styrene, acrylic resin, silicone, polymethylmethacrylate (PMMA), and phenol resin. Then, the first area 120a is subjected to a patterning process to form an opening 1201, and a bottom of the opening 1201 is connected to the first surface of the anode 120. Next, the second area 120b is subjected to a surface pad printing process. Specifically, a print head of a specific shape is set, and for example, a semicircular print head is provided to emboss on the second area 120b, then the first groove 12021 is formed by rolling the print head, and after that, a second embossing is performed on the first groove 12021 to form the second groove 12022. It is also possible to provide a print head with a specific shape as a main body of the print head, a plurality of coupling parts are arranged on a side and a bottom of the main body, and the first groove 12021 and the second groove 12022 are directly formed by embossing. When the number of the second grooves 12022 is greater than 1, the second grooves 12022 are embedded in the pixel definition layer 120, and an embedding angle of each of the second grooves 12022 ranges from 90 degrees to 180 degrees. It should be noted that, in an embodiment of the present invention, the shape of the print head can be adjusted according to actual requirements, which is not particularly limited herein.

It should be noted that in the method of manufacturing the display panel of the present invention, the sequence of the step S32 and the step S33 is not particularly limited. The opening 1201 may be formed first, followed by forming the grooves 1202; or the grooves 1202 may be formed first, followed by forming the opening 1201; or the opening 1201 and the grooves 1202 are formed at the same time.

Further, a depth of the grooves 1202 is smaller than a thickness of the pixel definition layer. Optionally, the depth of the grooves 1202 ranges between 0.2 μm and 1.2 μm.

Optionally, as shown in FIG. 3, in the method of manufacturing the display panel provided by the present invention, after the grooves 1202 is formed, the method further includes forming a filling layer 160, and the filling layer 160 fills at least part of the grooves 1202. The material of the filling layer 160 includes an inorganic material. The inorganic material includes at least one of silicon oxide, silicon nitride, silicon carbide, silicon oxynitride, or inorganic oxide. It is easy to understand that a bonding force between an inorganic material and a metal or a metal compound is better. Compared with the existing designs where adhesion between the cathode 140 and the pixel definition layer 120 relies on the Van der Waals force, the present invention improves the adhesiveness of the cathode 140, thereby effectively avoiding separation between the cathode 140 and the light-emitting layer 130 when the display panel is impacted or shocked, and an anti-bending strength and a strength of withstanding impact of the display panel are improved.

In the step S4, the light-emitting layer is formed in the opening 1201, wherein the material of the light-emitting layer includes a fluorescent light-emitting material, a quantum dot light-emitting material, and the like.

In the step S5, the cathode 140 is formed on the pixel definition layer 120 and the light-emitting layer 130, and a material of the cathode 140 fills the grooves 1202; wherein the cathode material includes a metal with a low power function such as silver, lithium, magnesium, calcium, strontium, aluminum, and indium, or a metal compound, or an alloy.

In the step S6, the encapsulation layer 150 is formed on the cathode 140, and the encapsulation layer 150 is configured to prevent the display panel from intrusion of water and oxygen which impacts the stability of the display panel.

Compared with the prior art, in the display panel and the manufacturing method thereof provided by embodiments of the present invention, the pixel definition layer is provided with the grooves, and a cathode material is filled in the grooves to increase a contact area between the cathode and the pixel definition layer and increase adhesion between the cathode and the pixel definition layer, so that the light-emitting layer is not easy to strip, thereby improving the stability of the display panel.

In addition, by providing a filling layer in the grooves, and making the material of the filling layer and the cathode material have the same polarity, the adhesion between the cathode and the pixel definition layer is further increased.

While the invention has been described by way of example and in terms of the preferred embodiments, it is to be understood that the invention is not limited to the disclosed embodiments. To the contrary, it is intended to cover various modifications and similar arrangements. Therefore, the scope of the appended claims should be accorded the broadest interpretation so as to encompass all such modifications and similar arrangements.

What is claimed is:

1. A display panel, comprising:
a thin-film transistor array substrate;
an anode disposed on the thin-film transistor array substrate;
a pixel definition layer disposed on the anode and the thin-film transistor array substrate, wherein the pixel definition layer comprises a first area and a second area, the first area is provided with an opening, a bottom of the opening is connected to the anode, and the second area is provided with a plurality of grooves;
a light-emitting layer disposed in the opening;
a cathode covering the light-emitting layer and the pixel defining layer; and
an encapsulation layer covering the cathode.

2. The display panel according to claim 1, wherein the grooves are formed by pad printing.

3. The display panel according to claim 1, wherein the grooves comprise a first groove and at least one second groove, and an opening of the at least one second groove is located on a sidewall and/or a bottom of the first groove.

4. The display panel according to claim 3, wherein an opening of the first groove is larger than the opening of the second groove.

5. The display panel according to claim 3, wherein the second groove at the bottom of the first groove is vertically embedded on the pixel definition layer, and an embedding angle of the second groove on each of opposite sides is greater than or equal to 0 degree and less than 90 degrees with respect to a horizontal plane of the pixel definition layer.

6. The display panel according to claim 1, wherein a depth of the grooves is smaller than a thickness of the pixel definition layer.

7. The display panel according to claim 6, wherein the depth of the grooves ranges between 0.2 μm and 1.2 μm.

8. The display panel according to claim 1, wherein the display panel further comprises a filling layer filling at least part of the grooves.

9. The display panel according to claim 8, wherein a material of the filling layer comprises an inorganic material.

10. The display panel according to claim 9, wherein the inorganic material comprises at least one of silicon oxide, silicon nitride, silicon carbide, silicon oxynitride, or inorganic oxide.

11. A method of manufacturing a display panel, comprising:
step A: forming a thin-film transistor array substrate;
step B: forming an anode on the thin-film transistor array substrate;
step C: forming a pixel definition layer, wherein the pixel definition layer comprises a first area and a second area, the first area is provided with an opening, and the second area is provided with a plurality of grooves;
step D: forming a light-emitting layer in the opening;
step E: forming a cathode to cover the light-emitting layer and the pixel definition layer; and
step F: forming an encapsulation layer to cover the cathode.

12. The method of manufacturing the display panel according to claim 11, wherein the step C comprises:
step c1: forming a pixel definition material layer;
step c2: patterning the first area to form the opening;
step c3: pad printing the second area to form the grooves, wherein the grooves comprise a first groove and at least one second groove, and an opening of the at least one second groove is located on a sidewall and/or a bottom of the first groove.

13. The method of manufacturing the display panel according to claim 12, wherein an opening of the first groove is larger than the opening of the second groove.

14. The method of manufacturing the display panel according to claim 12, wherein the second groove at the bottom of the first groove is vertically embedded on the pixel definition layer, and an embedding angle of the second groove on each of opposite sides is greater than or equal to 0 degree and less than 90 degrees with respect to a horizontal plane of the pixel definition layer.

15. The method of manufacturing the display panel according to claim 11, wherein a depth of the grooves is smaller than a thickness of the pixel definition layer.

16. The method of manufacturing the display panel according to claim 15, wherein a depth of the grooves ranges between 0.2 μm and 1.2 μm.

17. The method of manufacturing the display panel according to claim 11, wherein after the step C, the method of manufacturing the display panel further comprises a step G:
forming a filling layer to fill at least part of the grooves.

18. The method of manufacturing the display panel according to claim 17, wherein a material of the filling layer comprises an inorganic material.

19. The method of manufacturing the display panel according to claim 18, wherein the inorganic material comprises at least one of silicon oxide, silicon nitride, silicon carbide, silicon oxynitride, or inorganic oxide.
